(19) United States
(12) Patent Application Publication
(10) Pub. No.: US 2014/0283741 A1
(43) Pub. Date: Sep. 25, 2014

(54) METAL MATRIX COMPOSITE, EVAPORATION MASK MADE FROM THE SAME AND MAKING METHOD THEREOF

(71) Applicant: EverDisplay Optronics (Shanghai) Limited, Shanghai (CN)

(72) Inventors: Qiguo Zhang, Shanghai (CN); Chengpei Huang, Shanghai (CN); Chuwan Huang, Shanghai (CN)

(73) Assignee: EverDisplay Optronics (Shanghai) Limited, Shanghai (CN)

(21) Appl. No.: 13/958,394

(22) Filed: Aug. 2, 2013

(30) Foreign Application Priority Data
Mar. 22, 2013 (CN) 201310095144.5

(51) Int. Cl. H01L 51/56; C22C 49/08

(52) U.S. Cl. CPC H01L 51/56; C22C 49/08
USPC 118/504; 420/94; 164/493; 419/10

(57) ABSTRACT

The present application discloses a metal matrix composite for evaporation mask, comprising matrix and reinforcing phase dispersed in the matrix, wherein the matrix is iron-nickel alloy, the reinforcing phase is non-metallic particles, and the volume ratio of the non-metallic particles in the matrix is in the range from 20 vol % to 50 vol %. The present application also provides an evaporation mask made from the metal matrix composite and a making method thereof. The metal matrix composite according to the present application has a decreased density and an elevated elasticity modulus, and thereby is useful to prevent the evaporation mask from drooping due to gravity. Further, the method for making the evaporation mask according to the present application is beneficial to improve the overall performance of the evaporation mask, save raw materials and reduce the cost.

### CROSS-REFERENCE TO RELATED APPLICATIONS

This application claims the benefit of Chinese Patent Application No. 201310095144.5, filed on Mar. 22, 2013 and entitled “METAL MATRIX COMPOSITE FOR EVAPORATION MASK, EVAPORATION MASK AND METHOD FOR MANUFACTURING THE SAME”, the content of which is incorporated by reference herein in its entirety.

### TECHNICAL FIELD

The present application relates to a metal matrix composite, and particularly to a metal matrix composite for evaporation mask, an evaporation mask made from the same and a making method thereof.

### BACKGROUND

In comparison to liquid crystal displays (LCDs), organic light emitting diode (OLED) display devices have many advantages, such as self illumination, wide viewing angle and high contrast. The light emission mechanism of OLED comprises the followings: under the applied voltage, holes from anode and electrons from cathode inject into the organic layer sandwiched between anode and cathode, which has a laminated structure comprising hole injection layer, hole transport layer, light emitting layer, electron transport layer and electron injection layer, and then the holes and the electrons migrate into the light emitting layer where they encounter and recombine to give emission.

The organic layer can be made from either high molecular materials or low molecular materials, and when low molecular materials are used for the layer, it is preferred to form the layer by way of vacuum evaporation. For example, Chinese Patent Application No. CN200710127555 discloses a method for forming organic light emitting layer of OLED by evaporation deposition, wherein the organic light emitting layer is formed on the portion not being covered by the evaporation mask. When the evaporation mask is supported by the evaporation member with a predetermined space and for a preset period of time, it tends to droop in the middle due to gravity, which makes it difficult to form an acceptable organic light emitting layer. In particular, the resulted organic light emitting layer may fail to achieve the expected size and deviate from the expected position, leading to the display quality of OLED degraded. In order to overcome this problem, magnetic force can be applied to lift the evaporation mask made from metallic materials. However, in this way, the cost of OLED would increase, since an additional device for providing magnetic force is demanded. Particularly, the problem with respect to the droop becomes more considerable as the size of the evaporation mask increases, and accordingly the additional device for minimizing the droop becomes more complex, so that the cost of OLED further rises.

At present, the evaporation mask is usually made from Invar alloy, which is an iron alloy containing 36 wt % of Ni. Invar alloy has smaller expansion coefficient and better plasticity and impact ductility, and is relatively stable at a temperature of −80° C. to 230° C. However, the tensile strength and the hardness of Invar alloy are not high enough, and therefore it tends to bend when subjected to mechanical stretching or impacting. In addition, since Invar alloy has a higher density, the evaporated mask made from the alloy may readily droop in the middle.

Thus, a need exists for a material for an evaporation mask, an improved evaporation mask and an improved making method thereof, to solve the problem with respect to the droop due to gravity.

### SUMMARY OF THE INVENTION

In one aspect, the present application provides a metal matrix composite for evaporation mask, comprising matrix and reinforcing phase dispersed in the matrix, wherein the matrix is iron-nickel alloy, the reinforcing phase is non-metallic particles, and the volume ratio of the non-metallic particles in the matrix is in the range from 20 vol % to 50 vol %.

According to some embodiments, the iron-nickel alloy contains 30 wt % to 36 wt % of nickel.

According to some embodiments, the volume ratio of the non-metallic particles in the matrix is 50 vol %.

According to some embodiments, the non-metallic particles are selected from a group consisting of SiC particles, Al₂O₃ particles and AlN particles.

According to some embodiments, the non-metallic particles have a diameter from 1 μm to 30 μm.

In another aspect, the present application also provides a method for preparing the metal matrix composite for evaporation mask, comprising dispersing non-metallic particles into an iron-nickel alloy as reinforcing phase to form a particle reinforced metal matrix composite, wherein the volume ratio of the non-metallic particles in the matrix is in the range from 20 vol % to 50 vol %.

According to some embodiments, the method comprises: smelting the iron-nickel alloy at a temperature of 1390° C. to 1520° C. in a vacuum induction furnace or an electric arc furnace; uniformly dispersing the non-metallic particles into the molten iron-nickel alloy with magnetic stirring; and casting the molten iron-nickel alloy with the non-metallic particles dispersed to form a particle reinforced metal matrix composite.

According to some embodiments, the method comprises: uniformly mixing iron powder and nickel powder or pre-alloyed iron-nickel powder with non-metallic particles at room temperature by high-energy ball mill; subjecting the mixed powder to compression molding to form a molding product; and sintering the molding product at a temperature of 1390° C. to 1520° C. to form a particle reinforced metal matrix composite.

According to some embodiments, the method comprises: coating the non-metallic particles with nickel by high-pressure hydrogen reducing to prepare composite powder; uniformly mixing composite powder of the nickel coated non-metallic particles with iron powder at room temperature by high-energy ball mill; subjecting the mixed powder to compression molding to form a molding product; and sintering the molding product at a temperature of 1390° C. to 1520° C. to form a particle reinforced metal matrix composite.

According to some embodiments, the iron-nickel alloy contains 30 wt % to 36 wt % of nickel.

According to some embodiments, the volume ratio of the non-metallic particles in the matrix is 50 vol %.

According to some embodiments, the non-metallic particles are selected from a group consisting of SiC particles, Al₂O₃ particles and AlN particles.

According to some embodiments, the non-metallic particles have a diameter from 1 μm to 30 μm.

In still another aspect, the present application also provides an evaporation mask made from the above-mentioned metal matrix composite.

In still another aspect, the present application also provides a method for making the evaporation mask, comprising machining a casting made from the above-mentioned metal matrix composite to obtain an evaporation mask.

According to some embodiments, the iron-nickel alloy contains 30 wt % to 36 wt % of nickel.

According to some embodiments, the volume ratio of the non-metallic particles in the matrix is 50 vol %.

According to some embodiments, the non-metallic particles are selected from a group consisting of SiC particles, Al₂O₃ particles and AlN particles.

According to some embodiments, the non-metallic particles have a diameter from 1 μm to 30 μm.

In still another aspect, the present application also provides a method for making the evaporation mask, comprising: uniformly mixing iron powder and nickel powder or pre-alloyed iron-nickel powder with non-metallic particles at room temperature by high-energy ball mill; subjecting the mixed powder to compression molding in a mold for the evaporation mask to form a molding product; sintering the molding product at a temperature of 1390° C. to 1520° C. to obtain the evaporation mask, in which the matrix is the iron-nickel alloy and the reinforcing phase is the non-metallic particles.

According to some embodiments, the iron-nickel alloy contains 30 wt % to 36 wt % of nickel.

According to some embodiments, the volume ratio of the non-metallic particles in the matrix is 50 vol %.

According to some embodiments, the non-metallic particles are selected from a group consisting of SiC particles, Al₂O₃ particles and AlN particles.

According to some embodiments, the non-metallic particles have a diameter of 1 μm to 30 μm.

In still another aspect, the present application also provides a method for making the evaporation mask, comprising: coating the non-metallic particles with nickel by high-pressure hydrogen reducing to prepare composite powder; uniformly mixing composite powder of the nickel coated non-metallic particles with iron powder at room temperature by high-energy ball mill; subjecting the mixed powder to compression molding in a mold for the evaporation mask to form a molding product; and sintering the molding product at a temperature of 1390° C. to 1520° C. to obtain the evaporation mask, in which the matrix is the iron-nickel alloy and the reinforcing phase is the non-metallic particles.

According to some embodiments, the iron-nickel alloy contains 30 wt % to 36 wt % of nickel.

According to some embodiments, the volume ratio of the non-metallic particles in the matrix is 50 vol %.

According to some embodiments, the non-metallic particles are selected from a group consisting of SiC particles, Al₂O₃ particles and AlN particles.

According to some embodiments, the non-metallic particles have a diameter of 1 μm to 30 μm.

Compared with materials currently used in the art, the metal matrix composite for the evaporation mask according to the present application has a decreased density and an elevated elasticity modulus, and thereby is useful to prevent the evaporation mask from drooping due to gravity. Further, the method for making evaporation mask according to the present application is beneficial to improve the overall performance of the evaporation mask, save raw materials and reduce the cost.

### BRIEF DESCRIPTION OF THE DRAWINGS

FIG. 1 is a schematic view showing the structure of the metal matrix composite according to the present application.

FIG. 2 is a flow chart of the method for making the evaporation mask according to Example 1 of the present application.

FIG. 3 is a flow chart of the method for making the evaporation mask according to Example 2 of the present application.

### DETAILED DESCRIPTION

The present application will be described in more detail with reference to the drawings and examples. It should be understood that the examples are provided for illustrating rather than limiting the present application.

### EXAMPLE 1

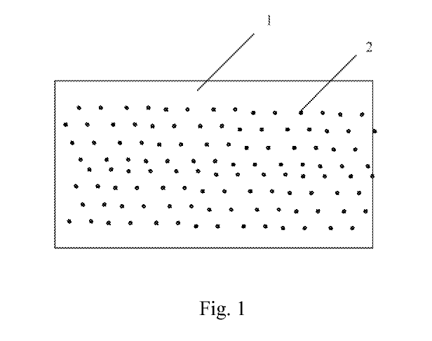

As shown in FIG. 1, in the metal matrix composite for the evaporation mask according to this example, the matrix 1 is iron-nickel alloy containing 35.4 wt % of nickel, and the reinforcing phase 2 is SiC particles dispersed in the matrix 1. As the matrix of the metal matrix composite, such iron-nickel alloy has better plasticity and impact ductility impact toughness, which can be further improved in properties such as strength, elastic modulus and hardness by reinforcing phase. As the reinforcing phase of the metal matrix composite, SiC has a density of 3.2 g/cm³ (only 40% of the density of Invar alloy) and a elastic modulus up to 450 GPa. Therefore, when SiC is added in the iron-nickel alloy matrix, the density of the matrix can be decreased and the elastic modulus of the matrix can be improved. Table 1 lists the density and the elastic modulus of the metal matrix composites with different volume ratios of SiC particles. As can be seen from Table 1, with the increase of the volume ratio of SiC particles in the iron-nickel alloy, the density of the composite is decreased and the elastic modulus of the composite is improved. However, in the practice, it is difficult for molding when excess amount of SiC particles is added. Thus, in this example, the volume ratio of SiC particles is preferably in the range from 20 vol % to 50 vol %.

TABLE 1

| Volume ratio of | Density | Elastic modulus |
|---|---|---|
| SiC particles (vo1 %) | (g/cm³) | (GPa) |
| 0 | 8.1 | 140 |
| 20 | 7.1 | 163 |
| 30 | 6.6 | 172 |
| 50 | 5.6 | 191 |

The reinforcing mechanism and effect of Al₂O₃ particles and AlN particles are similar to that of SiC particles, and would not be described herein in details.

The reinforcing effect may be poor when much larger or smaller non-metallic particles added, since it is difficult to uniformly disperse much larger non-metallic particles into the matrix and the expansion coefficient of much smaller non-metallic particles is large. Thus, in this example, the non-metallic particles with a diameter of 1 μm to 30 μm are employed.

The metal matrix composite according to this example has low density and high elastic modulus, which is suitable for making an evaporation mask, especially large evaporation mask, to prevent the mask from drooping and eliminate the need of additional devices for lifting the mask.

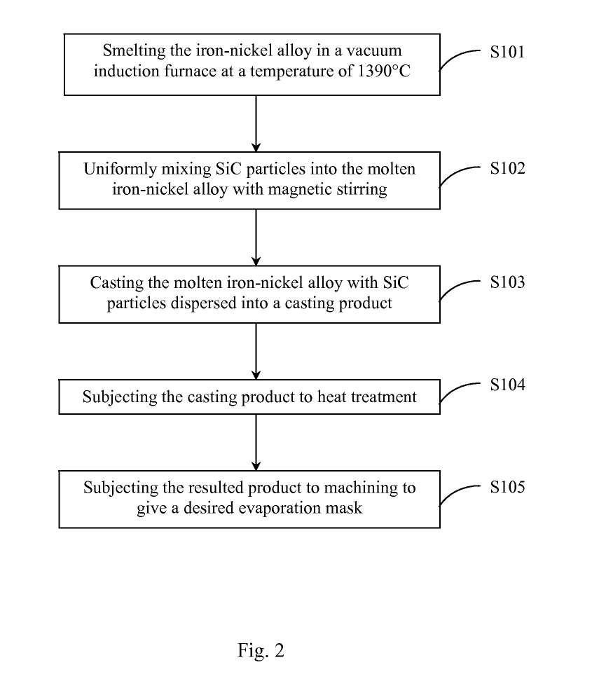

Next, referring to FIG. 2, the method for making an evaporation mask according to this example will be described in detail. In step S101, the iron-nickel alloy as described above is smelted in a vacuum induction furnace at a temperature of 1390° C. , and then in step S102, SiC particles is uniformly mixed into the molten iron-nickel alloy with magnetic stirring. In step 103, the molten iron-nickel alloy with SiC particles dispersed is casted into a casting product. In step 104, the casting product is subjected to heat treatment. The heat treatment comprises: heating and holding the product at 860±10° C., next, after water cooling, heating and holding the product again at 335±10° C., and then naturally cooling. In step 105, the resulted product is subjected to machining to give a desired evaporation mask.

Since the evaporation mask made according to this example is light, drooping in its middle due to gravity can be avoided. Thus, there is no need for additional devices and the cost is reduced accordingly.

### EXAMPLE 2

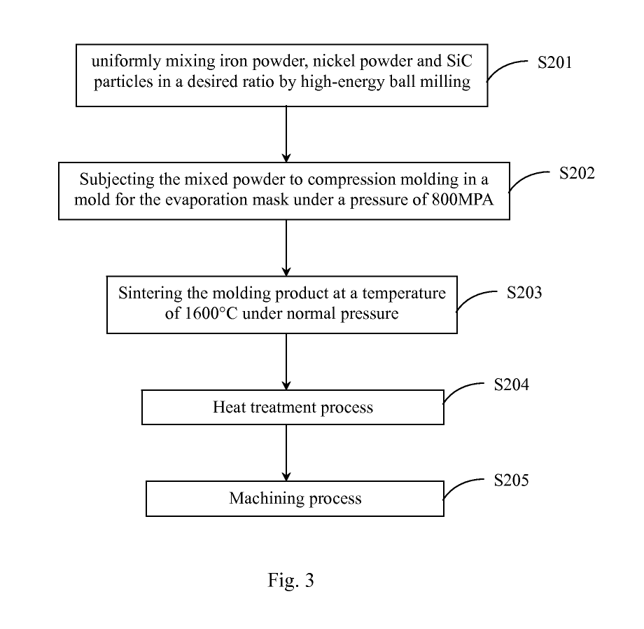

Referring to FIG. 3, a method for making the evaporation mask according to this example will be described in detail, wherein the metal matrix composite for the evaporation mask of this example is same as that of Example 1.

First, in step S201, iron powder, nickel powder and SiC particles are uniformly mixed in a desired ratio by high-energy ball milling, such that the resulted metal matrix composite contains 35.4 wt % of nickel and 50 vol % of SiC particles. The diameter of SiC particles is within the range from 1 μm to 30 μm. Next, in step S202, the mixed powder is subjected to compression molding in a mold for the evaporation mask under a pressure of 800 MPA. And then, in step S203, the molding product is sintered at a temperature of 1600° C. under normal pressure. After the conventional heat treatment in step S204 and machining processes in step S205, the evaporation mask made from the metal matrix composite is obtained.

In the metal matrix composite according to this example, the non-metallic particles as the reinforcing phase are dispersed more uniformly in the matrix. The evaporation mask obtained features lower weight, higher elastic modulus, and better resistance to impact and stretching.

Further, compared with Example 1, the consumption of raw materials for making the evaporation mask in this example is reduced due to the application of powder metallurgy process, and the evaporation mask is much readily obtained since it is moulded directly in the process of compression molding.

For the same reason as Example 1, the drooping of the evaporation mask in its middle due to gravity can be avoided. Thus, similarly, there is no need for additional devices and the cost is reduced accordingly.

### EXAMPLE 3

The method for making the evaporation mask and its advantages according to this example are similar as those according to Example 2, except using iron-nickel pre-alloyed powder instead of both iron powder and nickel powder, which results in the further improvement of plasticity and impact ductility.

### EXAMPLE 4

The method for making the evaporation mask and its advantages according to this example are similar as those according to Example 2, except using nickel coated SiC particles prepared by high-pressure hydrogen reducing instead of both nickel powder and SiC particles, which prevents SiC particles from reacting with iron powder at high temperature and improves the properties of the composite.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A metal matrix composite for an evaporation mask, comprising matrix and reinforcing phase dispersed in the matrix, wherein the matrix is iron-nickel alloy, the reinforcing phase is non-metallic particles, and the volume ratio of the non-metallic particles in the matrix is in the range from 20 vol % to 50 vol %.

2. The metal matrix composite according to claim 1, wherein the iron-nickel alloy contains 30 wt % to 36 wt % of nickel.

3. The metal matrix composite according to claim 2, wherein the iron-nickel alloy contains 35.4 wt % of nickel.

4. The metal matrix composite according to claim 1, wherein the volume ratio of the non-metallic particles in the matrix is 50 vol %.

5. The metal matrix composite according to claim 1, wherein the non-metallic particles are selected from a group consisting of SiC particles, Al₂O₃ particles and AlN particles.

6. The metal matrix composite according to claim 1, wherein the non-metallic particles have a diameter from 1 μm to 30 μm.

7. An evaporation mask made from the metal matrix composite according to claim 1.

8. A method for making the evaporation mask according to claim 7, comprising:
dispersing non-metallic particles into an iron-nickel alloy as reinforcing phase to form a smelting the iron-nickel alloy at a temperature of 1390° C. to 1520° C. in a vacuum induction furnace or an electric arc furnace; uniformly dispersing the non-metallic particles into the molten iron-nickel alloy with magnetic stirring; casting the molten iron-nickel alloy with the non-metallic particles dispersed to form a metal matrix composite casting; and machining the casting to obtain the evaporation mask, or
uniformly mixing iron powder and nickel powder or pre-alloyed iron-nickel powder with non-metallic particles at room temperature by high-energy ball mill; subjecting the mixed powder to compression molding in a mold for the evaporation mask to form a molding product; and sintering the molding product at a temperature of 1390° C. to 1520° C. to obtain the evaporation mask, or
coating the non-metallic particles with nickel by high-pressure hydrogen reducing to prepare composite powder; uniformly mixing composite powder at room temperature by high-energy ball mill; subjecting the mixed powder to compression molding in a mold for the evaporation mask to form a molding product; and sintering the molding product at a temperature of 1390° C. to 1520° C. to obtain the evaporation mask.

9. The method according to claim 8, wherein the iron-nickel alloy contains 30 wt % to 36 wt % of nickel.

10. The method according to claim 8, wherein the iron-nickel alloy contains 35.4 wt % of nickel.

11. The method according to claim 8, wherein the volume ratio of the non-metallic particles in the matrix is 50 vol %.

12. The method according to claim 8, wherein the non-metallic particles are selected from a group consisting of SiC particles, Al₂O₃ particles and AlN particles.

13. The method according to claim 8, wherein the non-metallic particles have a diameter from 1 μm to 30 μm.
